(19) United States
(12) Patent Application Publication
(10) Pub. No.: US 2026/0051344 A1
(43) Pub. Date: Feb. 19, 2026

(54) RECEIVER, ELECTRONIC SYSTEM INCLUDING THE SAME, AND OPERATING METHOD THEREOF

(71) Applicant: Samsung Electronics Co., Ltd., Suwon-si (KR)

(72) Inventors: Joungyeal KIM, Suwon-si (KR); Hyunjin KO, Suwon-si (KR); Jaewoo LEE, Suwon-si (KR); Soomin KIM, Suwon-si (KR)

(21) Appl. No.: 19/083,536

(22) Filed: Mar. 19, 2025

(30) Foreign Application Priority Data
Aug. 14, 2024 (KR) 10-2024-0109112

(51) Int. Cl. G11C 7/22; G06F 1/06; H03K 5/156

(52) U.S. Cl. CPC G11C 7/222; G06F 1/06; H03K 5/1565

(57) ABSTRACT

A receiver includes a duty adjustment module receiving a current code value and a first toggle signal, adjusting a duty cycle of the first toggle signal according to the current code value to generate a second toggle signal with an adjusted duty cycle, and outputting the second toggle signal, a duty monitoring module receiving the second toggle signal, and outputting a monitoring result value on a current code value, and a duty monitoring determination module determining one of the monitoring result value on the current code value and the final monitoring result value on an immediately previous code value as a final monitoring result value on the current code value.

### CROSS-REFERENCE TO RELATED APPLICATIONS

This application claims the benefit of Korean Patent Application No. 10-2024-0109112, filed on Aug. 14, 2024, in the Korean Intellectual Property Office, the disclosure of which is herein incorporated by reference in its entirety.

### BACKGROUND

### 1. Field of the Invention

Example embodiments relate to a receiver, an electronic system including the same, and an operating method thereof.

### 2. Description of the Related Art

A toggle signal may provide timing for performing communication or synchronized operations. The state of the toggle signal may transition through periodic rising or falling of a signal level. When a duty cycle of the toggle signal departs from a reference value (for example, 50 percent (%)), timing accuracy and data reliability may be reduced. To minimize this, a training process may be performed to find an optimum code value by adjusting the duty cycle of the toggle signal according to a code value, aiming at the reference value. However, the duty cycle may become non-uniform during the training process. In response to this case, a manner of processing duty cycles may be required.

### SUMMARY

An aspect provides a receiver in which the stability of a duty cycle is improved, an electronic system including the same, and an operating method thereof.

Example embodiments are not limited to the technical features described above, and other technical features may be inferred from the example embodiments below.

According to an aspect of the present disclosure, a receiver includes a duty adjustment module configured to receive a current code value and a first toggle signal from an external device, adjust a duty cycle of the first toggle signal according to the current code value to generate a second toggle signal with an adjusted duty cycle, and output the second toggle signal, a duty monitoring module configured to receive the second toggle signal, and output a monitoring result value on the current code value, wherein the monitoring result value indicates a result of comparing a current duty cycle of the second toggle signal and a reference value, and a duty monitoring determination module configured to determine, based on a compared value between the current code value and an immediately previous code value and a final monitoring result value on the immediately previous code value, one of the monitoring result value on the current code value and the final monitoring result value on the immediately previous code value as a final monitoring result value on the current code value.

According to an aspect of the present disclosure, an electronic system includes a driver configured to transmit a current code value and a toggle signal, and a receiver configured to receive the current code value and a first toggle signal from the driver, adjust a duty cycle of the first toggle signal according to the current code value to generate a second toggle signal with an adjusted duty cycle, obtain a monitoring result value on the current code value, wherein the monitoring result value indicates a result of comparing a current duty cycle of the second toggle signal and a reference value, obtain a compared value between the current code value and an immediately previous code value of the current code value, and determine, based on the compared value and a final monitoring result value on the immediately previous code value, one of the final monitoring result value on the immediately previous code value and the monitoring result value on the current code value as a final monitoring result value on the current code value.

According to an aspect of the present disclosure, an operating method of a device includes performing a training mode on a receiver of the device to set an adjusting code value, and performing a normal operation mode on the device after the training mode is completed, wherein a duty cycle of a toggle signal received in the normal operation mode is adjusted using the adjusting code value. Performing of the training mode includes receiving a current code value and a first toggle signal from an external device, adjusting a duty cycle of the first toggle signal according to the current code value to generate a second toggle signal with an adjusted duty cycle of the first toggle signal, obtaining a monitoring result value on the current code value indicating a result of comparing a current duty cycle of the second toggle signal and a reference value, wherein the current duty cycle of the second toggle signal corresponds to the adjusted duty cycle of the first toggle signal, generating a compared value between the current code value and an immediately previous code value of the current code value, determining, in response to the compared value and a final monitoring result value on the immediately previous code value, one of the final monitoring result value on the immediately previous code value and the monitoring result value on the current code value as a final monitoring result value on the current code value, and storing one of the current code value and the immediately previous code value as the adjusting code value in response to the final monitoring result value on the current code value which is different from the final monitoring result value on the immediately previous code value.

Additional aspects of example embodiments will be set forth in part in the description which follows and, in part, will be apparent from the description.

According to example embodiments, it is possible to provide a receiver in which the stability of a duty cycle is improved, an electronic system including the same, and an operating method thereof. According to example embodiments, it is possible to provide a uniform monitoring result value on a toggle signal whose duty cycle is sequentially adjusted. According to example embodiments, it is possible to provide an optimum adjusting code value for a duty cycle using a uniform monitoring result value.

The technical benefits achieved by example embodiments are not limited to those described above, and other technical benefits may be clearly understood by those skilled in the art from the appended claims.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a diagram for illustrating an electronic system according to example embodiments;

FIG. 2 is a diagram for illustrating a receiver according to example embodiments;

FIG. 3 is a diagram for illustrating a toggle signal and a code value according to example embodiments;

FIG. 4 is a diagram for illustrating a duty monitoring determination module according to example embodiments;

FIG. 5 is a diagram for illustrating a manner of obtaining a final monitoring result value according to example embodiments;

FIG. 6 is a diagram for illustrating an electronic system according to example embodiments;

FIG. 7 is a diagram for illustrating an electronic system according to example embodiments;

FIG. 8 is a diagram for illustrating a memory device according to example embodiments;

FIG. 9 is a diagram for illustrating a controller according to example embodiments; and

FIG. 10 is a diagram for illustrating an operating method of a receiver according to example embodiments.

### DETAILED DESCRIPTION

Terms used in example embodiments are selected from currently widely used general terms when possible while considering the functions in the present disclosure. However, the terms may vary depending on the intention of a person skilled in the art, precedents, or the emergence of new technology. There are also terms arbitrarily selected by the applicant, and in these cases, the meaning will be described in detail in the corresponding descriptions. Therefore, the terms used in the present disclosure are not to be construed simply as its designation but based on the meaning of the term and the overall context of the present disclosure.

Throughout the specification, when a part is described as “comprising” or “including” a component, it does not exclude another component but may further include another component unless otherwise stated. Furthermore, terms such as “ . . . unit,” “ . . . part,” and “ . . . module” described in the specification mean a unit that processes at least one function or operation, which may be implemented as hardware, software, or a combination thereof.

Hereinafter, example embodiments of the present disclosure will be described in detail with reference to the accompanying drawings so that those of ordinary skill in the art to which the present disclosure pertains may easily implement example embodiments of the present disclosure. However, the present disclosure may be implemented in multiple different forms and is not limited to the example embodiments described herein.

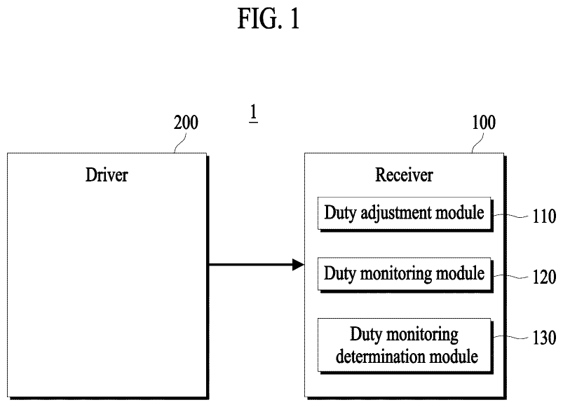

FIG. 1 is a diagram for illustrating an electronic system according to example embodiments.

Referring to FIG. 1, an electronic system 1 according to example embodiments of the present disclosure may include a driver 200 and a receiver 100.

The driver 200 may output a toggle signal to an external device. Here, the external device may include the receiver 100. In example embodiments, the driver 200 may generate a toggle signal whose a state (i.e., a signal level) is repeatedly transitioned. The state may be one of a first state and a second state. For example, the first state may be a low state in which a level (for example, a voltage level) of the toggle signal is less than a reference level, and the second state may be a high state in which the level of the toggle signal is greater than or equal to the reference level. For example, the first state may indicate a first value (for example, 0 or a low level) and the second state may indicate a second value (for example, 1 or a high level). In example embodiments, the driver 200 may include an oscillator or a signal generation circuit, which generates a toggle signal.

The receiver 100 may receive a toggle signal from an external device. Here, the external device may include the driver 200. The receiver 100 may receive a code value from the external device. In example embodiments, the driver 200 and the receiver 100 may be connected through a channel. The toggle signal may be transmitted and received through the channel. For example, the channel may include at least one of a wire, a bump, an interconnect of a printed circuit board, and a wireless channel.

The receiver 100 according to example embodiments may include a duty adjustment module 110, a duty monitoring module 120, and a duty monitoring determination module 130. Each of the duty adjustment module 110, the duty monitoring module 120, and the duty monitoring determination module 130 may be connected to each other through a bus. The term “module” as used in the present disclosure may be interpreted as comprising hardware and/or software components designed to perform specific functions. For example, a “module” may include specific and physical components such as circuit elements, processing elements, and memory elements, and should not be interpreted merely as a functional element.

The duty adjustment module 110 may, when receiving a code value and a toggle signal from an external device, adjust a duty cycle of the toggle signal according to the code value, and output the toggle signal with the adjusted duty cycle. For example, the duty adjustment module 110 may, when receiving a first code value and a first toggle signal from an external device, adjust a duty cycle of the first toggle signal according to the first code value, and output the first toggle signal with the adjusted duty cycle. Then, the duty adjustment module 110 may, when receiving a second code value and a second toggle signal from the external device, adjust a duty cycle of the second toggle signal according to the second code value, and output the second toggle signal with the adjusted duty cycle. The first code value may be an immediately previous code value of the second code value, and the second code value may be a current code value. For example, the duty adjustment module 110 may receive each of a plurality of code values consecutively, and the first code value and the second code value refer to two consecutive code values of the plurality of code values received by the duty adjustment module 110. In an embodiment, the code value may be received together with the toggle signal. In an embodiment, the code value may be received in advance of the toggle signal. The duty adjustment module 110 may, whenever receiving a code value and a toggle signal, output the toggle signal of which a duty cycle is sequentially adjusted. The duty cycle may be a proportion of time in which a state of the toggle signal is the first state (or the second state) within one time period. For example, the duty cycle may be a value of dividing the time of the first state by a sum value of the time of the first state and the time of the second state. For another example, the duty cycle may be a value of dividing the time of the second state by the sum value of the time of the first state and the time of the second state. In example embodiments, the duty cycle may be a value represented in percentage. In an embodiment, the duty adjustment module 110 may be implemented using a pulse-width modulation software in which a duty cycle of the toggle signal is incrementally increased or decreased. In an embodiment, the duty adjustment module 110 may include a phase-locked loop circuit which adjusts a duty cycle of the toggle signal by controlling the phase and frequency of the toggle signal. The present disclosure is not limited thereto. For example, the duty adjustment module 110 may be implemented using flip-flop based circuits or operational amplifier based circuits.

The duty monitoring module 120 may, when receiving the toggle signal adjusted according to each code value in the duty adjustment module 110, obtain a monitoring result value indicating a result of comparing a duty cycle for each code value and a reference value. For example, the duty monitoring module 120 may, when receiving the first toggle signal adjusted according to the first code value, obtain a first monitoring result value indicating a result of comparing a first duty cycle of the adjusted first toggle signal and the reference value. Then, the duty monitoring module 120 may, when the second toggle signal adjusted according to the second code value is received, obtain a second monitoring result value indicating a result of comparing a second duty cycle of the adjusted second toggle signal and the reference value. The first code value may be an immediately previous code value of the second code value, and the second code value may be a current code value. For example, the duty monitoring module 120 may obtain a monitoring result value on each code value. The reference value may be preset.

The duty monitoring determination module 130 may, according to a compared value between the first code value and the following second code value and a first final monitoring result value on the first code value, determine one of the first final monitoring result value on the first code value and the second monitoring result value on the second code value as a second final monitoring result value on the second code value. The first code value may be an immediately previous code value of the second code value, and the second code value may be a current code value. For example, the duty monitoring determination module 130 may determine to maintain the final monitoring result value on the current code value as a monitoring result value on the current code value or determine to change the final monitoring result value on the current code value to a final monitoring result value on the immediately previous code value.

In example embodiments, the second code value may be a code value received following the first code value among a plurality of code values which the receiver 100 consecutively receives. For example, the plurality of code values may be received in order of −2, −1, 0, 1, and 2. When the first code value is −2, the second code value may be −1. When the first code value is −1, the second code value may be 0. In the same manner, the second code value may be determined depending on the first code value. When the first code value is 2, the following second code value may not be present. In this case, a monitoring result value and a final monitoring result value on the second code value may not be present. The plurality of code values described above show merely one example embodiment and may be variously modified and implemented.

The duty monitoring determination module 130 may obtain a final monitoring result value on each code value. For example, the duty monitoring determination module 130 may obtain a plurality of final monitoring result values on a plurality of code values. The duty monitoring determination module 130 may obtain an adjusting code value by selecting one of the plurality of final monitoring result values in a training mode of the receiver 100. The duty adjustment module 110 may adjust a duty cycle of a toggle signal received after obtaining the adjusting code value (i.e., after the training mode is completed) according to the adjusting code value.

According to example embodiments of the present disclosure, the receiver 100 in which the stability of a duty cycle is improved, the electronic system 1 including the same, and an operating method thereof may be provided. According to example embodiments, a uniform monitoring result value on a toggle signal whose duty cycle is sequentially adjusted may be provided. According to example embodiments, an optimum adjusting code value for a duty cycle using a uniform monitoring result value may be provided. Hereinafter, example embodiments of the present disclosure are described in more detail with reference to the accompanying drawings.

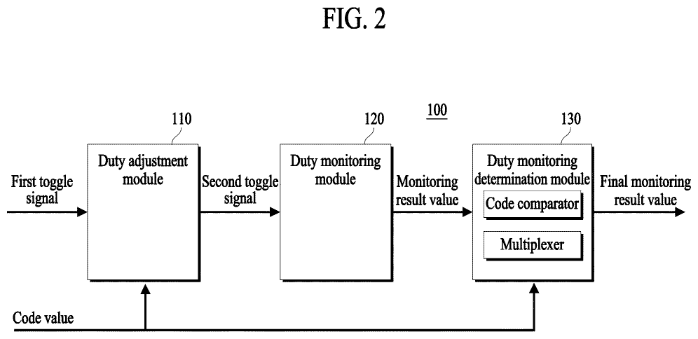

FIG. 2 is a diagram for illustrating a receiver according to example embodiments.

Referring to FIG. 2, the receiver 100 according to example embodiments may include the duty adjustment module 110, the duty monitoring module 120, and the duty monitoring determination module 130.

The duty adjustment module 110 may, when receiving a code value and a first toggle signal, adjust a duty cycle of the first toggle signal according to the code value. The code value and the first toggle signal may be received from an external device. The code value may be received prior to the first toggle signal or the code value may be received together with the first toggle signal. The duty adjustment module 110 may output a second toggle signal whose duty cycle is adjusted according to the code value.

In a detailed example embodiment, the duty adjustment module 110 may, when receiving a first code value and the first toggle signal from the external device, adjust the duty cycle of the first toggle signal according to the first code value. The duty adjustment module 110 may output the second toggle signal whose duty cycle is adjusted. Then, the duty adjustment module 110 may, when receiving a second code value among a plurality of code values and a following first toggle signal from the external device, adjust a duty cycle of the following first toggle signal according to the second code value and output a following second toggle signal. The duty adjustment module 110 may repeatedly perform the above operation whenever a following code value and a following first toggle signal are received. In example embodiments, an order in which the duty adjustment module 110 receives one of the plurality of code values may be an order of code values increasing from the smallest code value. In example embodiments, the order in which the duty adjustment module 110 receives one of the plurality of code values may be an order of code values decreasing from the greatest code value. In example embodiments, the order in which the duty adjustment module 110 receives one of the plurality of code values may be an order arbitrarily selected.

In example embodiments, the plurality of code values may be received from the external device one by one. The plurality of code values may be different values from each other. The code value may correspond to a time by which a duty cycle is adjusted. In example embodiments, each of the plurality of code values may be an integer. For example, a code value of (+) sign may indicate increasing a duty cycle, and a code value of (−) sign may indicate decreasing a duty cycle. A magnitude of the code value may indicate a length (or level) of time for adjusting (for example, increasing or decreasing) a duty cycle.

In example embodiments, the duty monitoring determination module 130 may receive one of the plurality of code values. For example, the duty monitoring determination module 130 may receive one code value from the external device. For another example, the duty monitoring determination module 130 may receive one code value from the duty adjustment module 110. The code value received by the duty monitoring determination module 130 may be a code value used to adjust a duty cycle in the duty adjustment module 110.

In example embodiments, the duty monitoring module 120 may receive the second toggle signal whose duty cycle is adjusted according to the code value. The duty monitoring module 120 may obtain the duty cycle of the second toggle signal for the code value. The duty monitoring module 120 may obtain and output a monitoring result value on the code value. The monitoring result value may indicate a result of comparing the duty cycle for the code value and a reference value. The monitoring result value may be briefly referred to as a result value.

In example embodiments, the plurality of code values may include the first code value and the second code value. For example, the first code value may be an immediately previous code value of the second code value. The duty monitoring module 120 may receive the second toggle signal adjusted according to the first code value from the duty adjustment module 110. The duty monitoring module 120 may obtain and output a first monitoring result value on the first code value which indicates a result of comparing a first duty cycle of the second toggle signal and the reference value. Then, the duty monitoring module 120 may receive the following second toggle signal adjusted according to the second code value from the duty adjustment module 110. The duty monitoring module 120 may obtain and output a second monitoring result value on the second code value which indicates a result of comparing a second duty cycle of the following second toggle signal and the reference value.

In example embodiments, the duty monitoring module 120 may include a comparator. For example, the comparator may, when each duty cycle for each code value and the reference value are inputted, output a result value indicating a result of comparing each duty cycle and the reference value. The example embodiment described above is merely one example embodiment, and the duty monitoring module 120 may be implemented as various circuits that determine whether a duty cycle is greater than or equal to the reference value and output a monitoring result value thereon.

In example embodiments, the reference value may be a value corresponding to 50 percent (%) or 0.5. However, this is merely one example embodiment, and the reference value may be modified to various values and implemented. In example embodiments, the result value may be one of a first value and a second value. For example, the first value may indicate that a duty cycle is less than the reference value, and the second value may indicate that a duty cycle is greater than or equal to the reference value. For another example, the first value may indicate that a duty cycle is less than or equal to the reference value, and the second value may indicate that a duty cycle is greater than the reference value. For example, the first value may be 0, and the second value may be 1. For another example, the first value may be 1, and the second value may be 0. Descriptions below suppose that the first value is 0 and the second value is 1.

In example embodiments, the duty monitoring module 120 may obtain the duty cycle for the code value from a flip signal of the second toggle signal in which a state of the second toggle signal with the adjusted duty cycle is reversed. For example, the flip signal may be a complementary signal of the second toggle signal. The duty monitoring module 120 may obtain the monitoring result value indicating a result of comparing the duty cycle and the reference value. In example embodiments, the duty monitoring module 120 may include a flip circuit. For example, the flip circuit may generate a flip signal for reversing the state of the second toggle signal. For example, a first state of the flip signal may be the reverse of a second state of the second toggle signal, and a second state of the flip signal may be the reverse of a first state of the second toggle signal.

In example embodiments, the duty monitoring determination module 130 may, according to a compared value between an immediately previous code value and a current code value and a final monitoring result value on the immediately previous code value, determine one of a monitoring result value on the current code value and the final monitoring result value on the immediately previous code value as a final monitoring result value on the current code value. The final monitoring result value may be briefly referred to as a final result value.

In example embodiments, the duty monitoring determination module 130 may, according to a compared value between the first code value and the second code value and a first final monitoring result value on the first code value, determine one of the first final monitoring result value and the second monitoring result value as a final monitoring result value on the second code value. The second code value may be the following order of the first code value. For example, the first code value may be a code value of N-th order, and the second code value may be a code value of N+1-th order. N is a natural number greater than or equal to 1. The first final monitoring result value may be the final monitoring result value on the first code value obtained in the duty monitoring module 120. The second monitoring result value may be the monitoring result value on the second code value obtained in the duty monitoring module 120.

In example embodiments, a second final monitoring result value on the second code value may be the second monitoring result value or the first final monitoring result value. For example, the duty monitoring determination module 130 may, according to an order of the code value and the first final monitoring result value, maintain and determine the second monitoring result value on the second code value as the second final monitoring result value on the second code value or determine the first final monitoring result value on the first code value instead of the second monitoring result value on the second code value as the second final monitoring result value on the second code value. By repeating the above process, a final monitoring result value on each of the plurality of code values may be determined. According to example embodiments of the present disclosure, an adjusting code value for adjusting a duty cycle of a toggle signal may be obtained by using the final monitoring result value. The duty cycle of the toggle signal, which is adjusted by using the adjusting code value, may be close to the reference value.

In example embodiments, the duty monitoring determination module 130 may obtain a compared value (or code compared value) between the first code value and the second code value. The compared value between the first code value and the second code value may indicate that an order of the code value is increasing code values or decreasing code values.

In example embodiments, the duty monitoring determination module 130 may include a code comparator. For example, the code comparator may, when receiving the first code value and the second code value, output the compared value between the first code value and the second code value. For example, the second code value may be a current code value, and the first code value may be an immediately previous code value of the current code value. In example embodiments, the duty monitoring determination module 130 may include a multiplexer. For example, the multiplexer may output one of a plurality of input signals according to a selection signal. For example, the input signal may include the first final monitoring result value on the first code value and the second monitoring result value on the second code value. The selection signal may include the compared value between the first code value and the second code value and the first final monitoring result value on the first code value.

In example embodiments, the duty monitoring determination module 130 may select and determine one of the final monitoring result values on the plurality of code values as the adjusting code value. The duty monitoring determination module 130 may store the adjusting code value. In example embodiments, the duty monitoring determination module 130 may, when the first final monitoring result value on the first code value and the second final monitoring result value on the second code value following the first code value are different, store one of the first code value and the second code value as the adjusting code value.

In example embodiments, the duty adjustment module 110 may receive a mode register write command from the external device. Then, the duty adjustment module 110 may, when receiving the first code value and a toggle signal, adjust a duty cycle of the toggle signal according to the first code value, and output the toggle signal with the adjusted duty cycle. Then, the duty adjustment module 110 may, when receiving the second code value and a following toggle signal, adjust a duty cycle of the toggle signal according to the second code value, and output the toggle signal with the adjusted duty cycle. The above operations may be performed sequentially until the adjusting code value described above is stored (i.e., when a training mode of the receiver 100 completes).

In another example embodiment, when a preset event occurs, the receiver 100 may enter into a training mode. While the receiver 100 is in the training mode, operations described above from receiving the first toggle signal to storing the adjusting code value may be performed sequentially. For example, the preset event may include at least one of an event of the receiver 100 in a turn-off state being turned on, an event of a duty cycle of a toggle signal obtained by the duty monitoring module 120 departing from a reference range, and an event of a specific command (for example, mode register write command) being received from an external device. In example embodiments, after the adjusting code value is stored, the receiver 100 may be changed from the training mode to a general mode (e.g., a normal operation mode such as a read or write operation in a memory device).

In example embodiments, the duty adjustment module 110 may, when the following toggle signal is received, adjust a duty cycle of the following toggle signal according to the adjusting code value. In example embodiments, the following toggle signal may be a toggle signal received after the adjusting code value is stored. In example embodiments, the following toggle signal may be a toggle signal received while the receiver 100 is in the general mode.

According to the present disclosure, when comparing consecutive final monitoring result values in a direction of increasing (or decreasing) code values among final monitoring result values for each code value, the number of times a value changes may occur once. For example, a boundary divided into the final monitoring result value may occur at a single point. According to the present disclosure, flickering may not be observed, in which a value changes two or more times in the final monitoring result value. According to the present disclosure, by removing a non-uniform result value according to duty cycle adjustment, a uniform final monitoring result value may be provided. According to example embodiments, an optimum adjusting code value for a duty cycle using a uniform final monitoring result value may be provided.

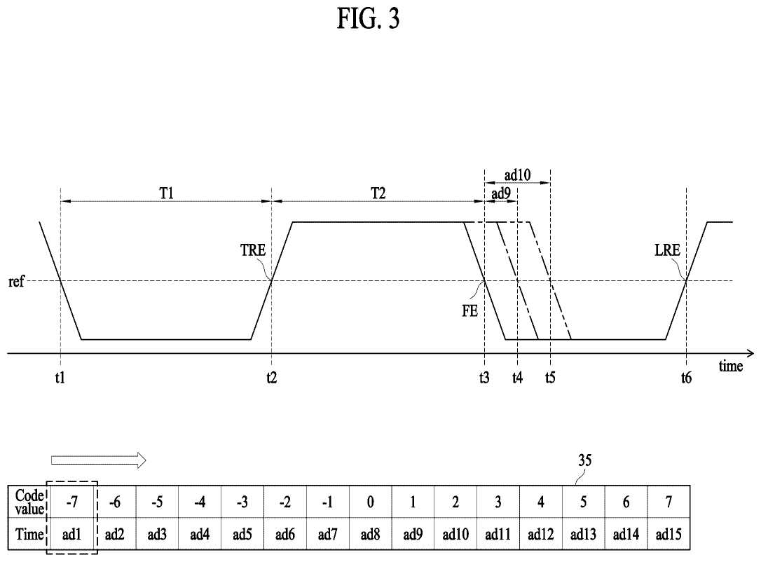

FIG. 3 is a diagram for illustrating a toggle signal and a code value according to example embodiments.

Referring to FIG. 3, the toggle signal according to example embodiments may be a signal of which a state is transitioned.

In example embodiments, the duty adjustment module 110 may, when receiving the toggle signal from an external device, adjust a duty cycle of the toggle signal according to a default code value and output the toggle signal with the adjusted duty cycle. For example, the default code value may be 0.

In example embodiments, the duty adjustment module 110 may, when receiving a first code value and the toggle signal from the external device, adjust the duty cycle of the toggle signal according to the first code value, and output the toggle signal with the adjusted duty cycle. Then, the duty adjustment module 110 may, when receiving a second code value and the toggle signal from the external device, adjust the duty cycle of the toggle signal according to the second code value, and output the toggle signal with the adjusted duty cycle. Thus, the duty adjustment module 110 may adjust the duty cycle of the toggle signal according to a received code value, and output the toggle signal with the adjusted duty cycle.

For example, it is supposed that an order of receiving code values is an order of code values increasing from the smallest code value. The duty adjustment module 110 may receive the first code value (for example, −7). The duty adjustment module 110 may adjust the duty cycle of the toggle signal by a first time (for example, ad1) corresponding to the first code value (for example, −7) and output the toggle signal with the adjusted duty cycle. For example, the toggle signal adjusted according to the first code value (for example, −7) may be a signal whose timing is advanced by the first time (for example, ad1) toward a leading rising edge LRE which will be disclosed below. In addition, the duty adjustment module 110 may receive a second code value (for example, −6) following the first code value (for example, −7). In this case, the duty adjustment module 110 may adjust by a second time (for example, ad2) corresponding to the second code value (for example, −6) and output the toggle signal with the adjusted duty cycle. In such a manner, the toggle signal adjusted according to the code value may be outputted. The toggle signal adjusted according to a ninth code value (for example, 1) may be a signal whose timing is delayed by a ninth time (for example, ad9). The toggle signal adjusted according to a tenth code value (for example, 2) may be a signal whose timing is delayed by a tenth time (for example, ad10). In an embodiment, the duty adjustment module 110 may shift the timing of a falling edge of the toggle signal. For example, the toggle signal may include a leading rising edge LRE at a sixth time point t6, a trailing rising edge TRE at a second time point t2, and a falling edge FE at t3. At the ninth code value of 1, the falling edge FE may be shifted toward the leading rising edge LRE by the ninth time (for example, ad9), and at the tenth code value of 2, the falling edge FE may be shifted toward the leading rising edge LRE by the tenth time (for example, ad10). The falling edge FE may be shifted according to a code value, but the trailing rising edge TRE and the leading rising edge LRE stay unchanged at the time points t2 and t6 in a training mode.

Information 35 of a code value and a time may be stored in the duty adjustment module 110 in advance. In another example embodiment, the information 35 of the code value and the time may be received from the external device.

In example embodiments, the duty monitoring module 120 may identify a first time for which a state of the toggle signal adjusted according to each code value is maintained as a first state and a second time for which the state is maintained as a second state. In example embodiments, the duty monitoring module 120 may obtain a value of dividing the first time by a sum value of the first time and the second time as a duty cycle for each code value. In another example embodiment, the duty monitoring module 120 may obtain a value of dividing the second time by a sum value of the first time and the second time as a duty cycle of the toggle signal. For example, the first state may be a low state and the second state may be a high state. For another example, the first state may be a high state and the second state may be a low state.

In a detailed example embodiment, the duty monitoring module 120 may identify a first time for which a state of the toggle signal adjusted according to the first code value is maintained as the first state and a second time for which the state is maintained as the second state and obtain a value of dividing the first time by a sum value of the first time and the second time as a first duty cycle for the first code value. In addition, the duty monitoring module 120 may identify a third time for which a state of the toggle signal adjusted according to the second code value is maintained as the first state and a fourth time for which the state is maintained as the second state and obtain a value of dividing the third time by a sum value of the third time and the fourth time as a second duty cycle for the second code value.

In an embodiment, the duty monitoring module 120 may identify a falling edge and a rising edge of the toggle signal. The falling edge may be a time point at which the level of the toggle signal is changed to be less than a reference level ref, and the rising edge may be a time point at which the level of the toggle signal is changed to be greater than or equal to the reference level ref. The first time may be a time from the falling edge to the rising edge, and the second time may be a time from the rising edge to the falling edge.

For example, it is supposed that the falling edge of the toggle signal is a first time point t1, the rising edge is a second time point t2, and a following falling edge is a third time point t3. In example embodiments, the duty monitoring module 120 may obtain a value of dividing a first time T1 by a sum value of the first time T1 and a second time T2 as a duty cycle. The first time T1 may be a time from the first time point t1 to the second time point t2 in which a low state is maintained, and the second time T2 may be a time from the second time point t2 to the third time point t3 in which a high state is maintained. In another example embodiment, the duty monitoring module 120 may obtain a value of dividing the second time T2 by a sum value of the first time T1 and the second time T2 as a duty cycle.

In example embodiments, the duty monitoring module 120 may obtain a result value indicating a result of comparing a duty cycle for each code value and a reference value. For example, the duty monitoring module 120 may obtain a plurality of result values on a plurality of code values.

The duty monitoring module 120 may, when the first duty cycle for the first code value is less than the reference value, obtain a first value as a first monitoring result value on the first code value. The duty monitoring module 120 may, when the first duty cycle for the first code value is greater than or equal to the reference value, obtain a second value as the first monitoring result value on the first code value. The first value may be 0, and the second value may be 1. For another example, the first value may be 1, and the second value may be 0.

The duty monitoring module 120 may, when the second duty cycle for the second code value is less than the reference value, obtain the first value as a second monitoring result value on the second code value, and when the second duty cycle for the second code value is greater than or equal to the reference value, obtain the second value as the second monitoring result value on the second code value. The first value may be 0, and the second value may be 1. For another example, the first value may be 1, and the second value may be 0.

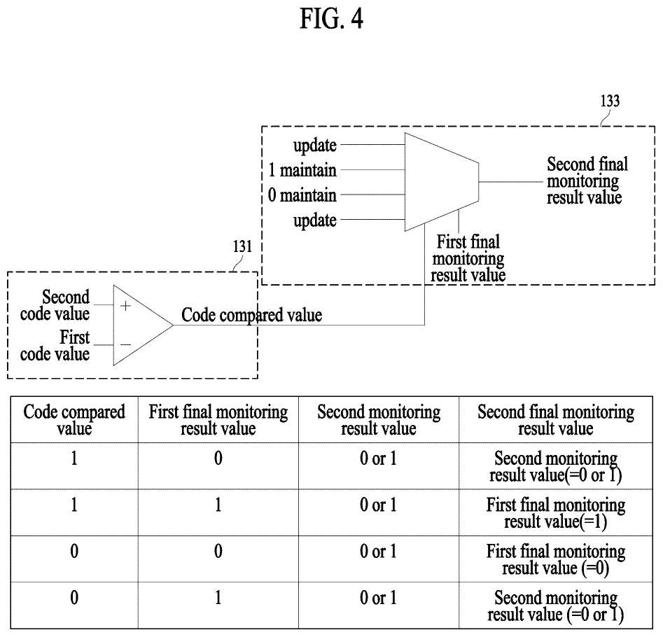

FIG. 4 is a diagram for illustrating a duty monitoring determination module according to example embodiments.

Referring to FIG. 4, the duty monitoring determination module 130 according to example embodiments may include at least one of a comparator 131 and a multiplexer 133.

The comparator 131 may, when a second code value is greater than a first code value, output a third value as a code compared value. The code compared value may be the compared value described above. The comparator 131 may, when the second code value is less than the first code value, output a fourth value as the code compared value. The first code value may be a code value of N-th order, and the second code value may be a code value of N+1-th order. For example, when the second code value is a current code value, the first code value may be an immediately previous code value of the current code value. In example embodiments, the third value may be 1, and the fourth value may be 0. The third value may indicate an order of increasing code values or (+) sign, and the fourth value may indicate an order of decreasing code values or (−) sign. In another example embodiment, the third value may be 0, and the fourth value may be 1.

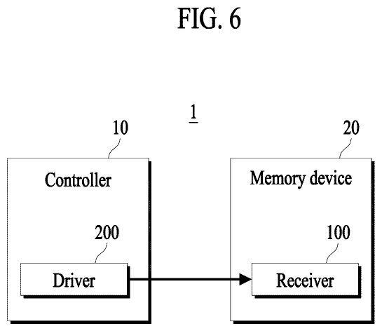

In example embodiments, the multiplexer 133 may, according to the code compared value outputted from the comparator 131 and a first final monitoring result value on the first code value, output one of a second monitoring result value on the second code value and the first final monitoring result value on the first code value as a second final monitoring result value on the second code value. For example, the multiplexer 133 may, according to the code compared value outputted from the comparator 131 and the first final monitoring result value on the immediately previous code value, output one of the second monitoring result value on the current code value and the first final monitoring result value on the immediately previous code value as the second final monitoring result value on the current code value. In an embodiment, the first final monitoring result value on the immediately previous code value may be stored in a mode register and read from the mode register. The mode register will be described with reference to FIG. 6. The first final monitoring result value may be briefly referred to as a first final result value. The second monitoring result value may be briefly referred to as a second result value. The second final monitoring result value may be briefly referred to as a second final result value.

For example, input signals of the multiplexer 133 may include the first final monitoring result value and the second monitoring result value. For another example, the input signal of the multiplexer 133 may include a first maintained value (for example, 0), a second maintained value (for example, 1), a first updated value (for example, 0), and a second updated value (for example, 1). Referring to FIG. 4, for example, “update” may be a control signal that disregards the second monitoring result value and outputs the first final monitoring result value as the second final monitoring result value. “1 maintain” may be a control signal that outputs the second monitoring result value as the second final monitoring result value when its value is 1. “0 maintain” may be a control signal that outputs the second monitoring result value as the second final monitoring result value when its value is 0. One of the control signals may be selected based on the code compared value and the first monitoring result value.

In a detailed example embodiment, the multiplexer 133 may, when the code compared value is the third value (for example, 1) and the first final monitoring result value is a first value (for example, 0), output the second monitoring result value as the second final monitoring result value on the second code value. In this case, the second monitoring result value may be 0 or 1, and the second final monitoring result value on the second code value may be maintained as the second monitoring result value and outputted.

In example embodiments, the multiplexer 133 may, when the code compared value is the third value (for example, 1) and the first final monitoring result value is a second value (for example, 1), output the first final monitoring result value as the second final monitoring result value on the second code value. In this case, the second final monitoring result value on the second code value may be updated to the second value (for example, 1) which is the first final monitoring result value and outputted.

In example embodiments, the multiplexer 133 may, when the code compared value is the fourth value (for example, 0) and the first final monitoring result value is the first value (for example, 0), output the first final monitoring result value as the second final monitoring result value on the second code value. In this case, the second final monitoring result value on the second code value may be updated to the first value (for example, 0) which is the first final monitoring result value and outputted.

In example embodiments, the multiplexer 133 may, when the code compared value is the fourth value (for example, 0) and the first final monitoring result value is the second value (for example, 1), output the second monitoring result value as the second final monitoring result value on the second code value. In this case, the second monitoring result value may be 0 or 1, and the second final monitoring result value on the second code value may be maintained as the second monitoring result value and outputted.

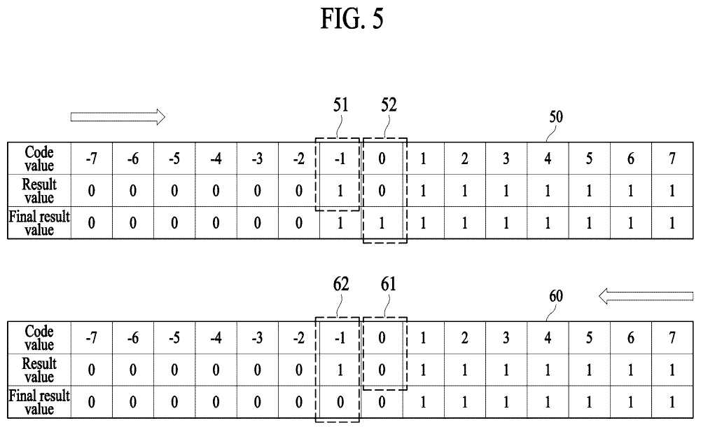

FIG. 5 is a diagram for illustrating a manner of obtaining a final monitoring result value according to example embodiments.

Referring to FIG. 5, a first table 50 according to example embodiments indicates adjusting a duty cycle of a toggle signal when a code value is received in an order of increasing code values, and a second table 60 indicates adjusting a duty cycle of a toggle signal when a code value is received in an order of decreasing code values. A result value may be the monitoring result value described above, and a final result value may be the final monitoring result value.

Referring to the first table 50, the duty adjustment module 110 may, when receiving code values one by one in an order from code value −7 to code value 7, output a toggle signal of which a duty cycle is adjusted according to each code value. The duty monitoring module 120 may obtain a monitoring result value on each of code value −7 to code value 7. The duty monitoring determination module 130 may determine a final monitoring result value on a current code value using a compared value between the current code value and an immediately previous code value and one of a monitoring result value on the current code value and a final monitoring result value on the immediately previous code value. The compared value may indicate an order of increasing code values.

In a detailed example embodiment, it is supposed that the immediately previous code value is −1 and the current code value is 0. The duty monitoring determination module 130 may identify the order (or direction) of increasing code values according to the compared value between the current code value and the immediately previous code value. In a first portion 51, the duty monitoring determination module 130 may identify that the final monitoring result value on the immediately previous code value is 1 and the monitoring result value on the current code value is 0. In a second portion 52, the duty monitoring determination module 130 may not maintain a current result value on the current code value and may determine an immediately previous result value, 1, on the immediately previous code value as the final monitoring result value on the current code value.

For an initially received code value among a plurality of code values, the duty adjustment module 110 may maintain and determine a monitoring result value on the initially received code value as a final monitoring result value on the initially received code value. In this case, this is because no immediately previous code value is present. For example, in the order of increasing code values, the initially received code value may be the smallest value, −7.

Referring to the second table 60, the duty adjustment module 110 may, when receiving code values one by one in an order from code value 7 to code value −7, output a toggle signal of which a duty cycle is adjusted according to each code value. The duty monitoring module 120 may obtain a result value on each of code value 7 to code value −7. The duty monitoring determination module 130 may determine a final monitoring result value on a current code value using a compared value between the current code value and an immediately previous code value and one of a monitoring result value on the current code value and a final monitoring result value on the immediately previous code value. The compared value may indicate an order of decreasing code values.

In a detailed example embodiment, it is supposed that the immediately previous code value is 0 and the current code value is −1. The duty monitoring determination module 130 may identify the order (or direction) of decreasing code values according to the compared value between the current code value and the immediately previous code value. In addition, as in a third portion 61, the duty monitoring determination module 130 may identify that the final monitoring result value on the immediately previous code value is 0 and the monitoring result value on the current code value is 1. In this case, as in a fourth portion 62, the duty monitoring determination module 130 may not maintain the monitoring result value on the current code value and may determine the final monitoring result value, 0, on the immediately previous code value as the final monitoring result value on the current code value.

For an initially received code value among a plurality of code values, the duty adjustment module 110 may maintain and determine a monitoring result value on the initially received code value as a final monitoring result value on the initially received code value. For example, in the order of decreasing code values, the initially received code value may be the greatest value, 7.

In example embodiments, the duty monitoring determination module 130 may determine one of a plurality of final monitoring result values as an adjusting code value. The adjusting code value may be a code value for adjusting a duty cycle of a toggle signal received after a training mode is completed.

In example embodiments, the duty monitoring determination module 130 may, when a final monitoring result value on an immediately previous code value and a final monitoring result value on a current code value are different, determine one of the immediately previous code value and the current code value as the adjusting code value. For example, when a final monitoring result value on an immediately previous code value, −2, is 0 and a final monitoring result value on a following current code value, −1, is 1 in the first table 50, the duty monitoring determination module 130 may determine one of the immediately previous code value, −2, and the current code value, −1, as the adjusting code value. For example, the duty monitoring determination module 130 may determine the immediately previous code value, −2, which is smaller between the immediately previous code value, −2, and the current code value, −1, as the adjusting code value. For another example, the duty monitoring determination module 130 may determine the current code value, −1, which is greater between the immediately previous code value, −2, and the current code value, −1, as the adjusting code value.

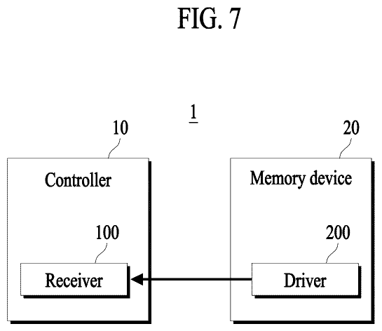

FIG. 6 is a diagram for illustrating an electronic system according to example embodiments. FIG. 7 is a diagram for illustrating an electronic system according to example embodiments.

Referring to FIGS. 6 and 7, the electronic system 1 according to example embodiments may be various types of electronic apparatuses such as a smartphone, a computer, a server, a television (TV), a tablet, a game machine, an Internet of Things device, a wearable device, and an artificial intelligence learning device, or battery management system and in-vehicle infotainment system.

The electronic system 1 may include the driver 200 and the receiver 100 connected to the driver 200. The driver 200 may transmit a toggle signal. The receiver 100 may receive the toggle signal. The receiver 100 may include the duty adjustment module 110 configured to, when receiving a current code value and the toggle signal, adjust a duty cycle of the toggle signal according to the current code value, the duty monitoring module 120 configured to obtain a current duty cycle of the toggle signal whose duty cycle is adjusted and obtain a monitoring result value indicating a result of comparing the current duty cycle and a reference value, and the duty monitoring determination module 130 configured to, according to a compared value between an immediately previous code value and the current code value and a final monitoring result value on the immediately previous code value, determine one of the final monitoring result value on the immediately previous code value and the monitoring result value on the current code value as a final monitoring result value on the current code value. Hereinafter, duplicating the above descriptions of the receiver 100 and the driver 200 is omitted.

The electronic system 1 may include a controller 10 and a memory device 20.

The controller 10 may control the memory device 20. The controller 10 may transmit commands for controlling the operation of the memory device 20 and addresses. The controller 10 may transmit data to be stored in the memory device 20. The controller 10 may receive data stored in the memory device 20.

The memory device 20 may perform the operation according to the control of the controller 10. The memory device 20 may store data received from the controller 10 or provide the stored data to the controller 10. In example embodiments, the memory device 20 may be implemented as a dynamic random access memory (DRAM) device, a synchronous RAM (SDRAM) device, a low power double data rate (LPDDR) SDRAM device, a static RAM (SRAM) device, a NAND flash memory device, a NOR flash memory device, a resistive RAM (RRAM) device, a ferroelectric RAM (FRAM) device, a phase-change RAM (PRAM) device, a magnetic RAM (MRAM) device, a solid state drive (SSD), a memory card, or a universal flash storage (UFS). However, this is merely one example embodiment, and the memory device 20 is not limited to the listed types and may be implemented as various types of semiconductor memory devices.

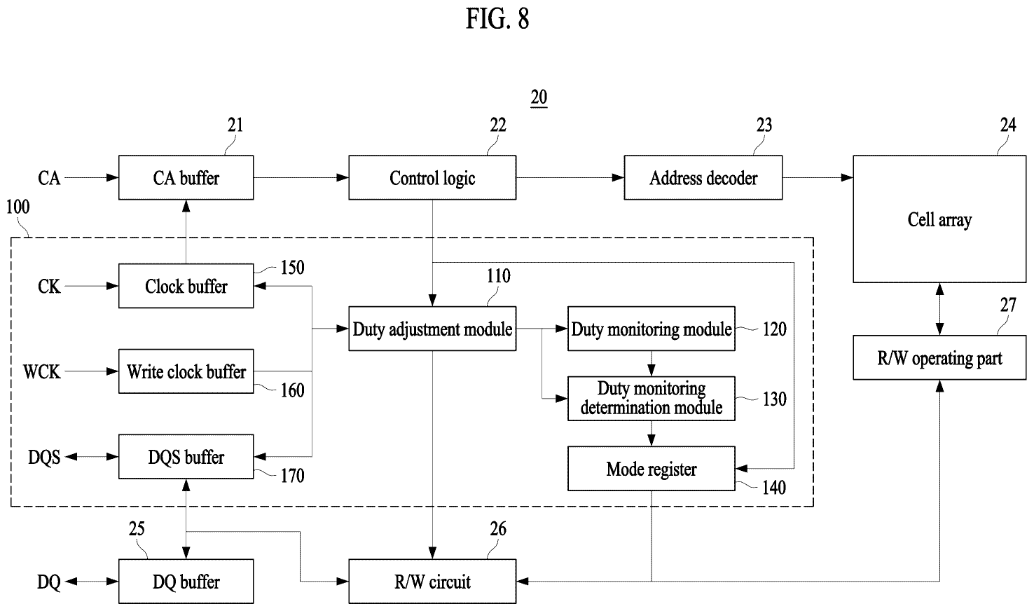

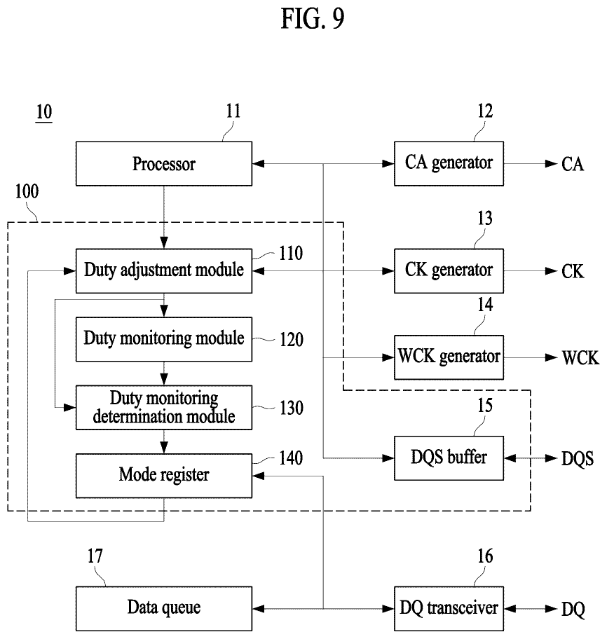

In example embodiments, the memory device 20 may include one of the driver 200 and the receiver 100. The controller 10 may include another of the driver 200 and the receiver 100. Referring to FIG. 6, the controller 10 may include the driver 200, and the memory device 20 may include the receiver 100. This is described in detail with reference to FIG. 8. Referring to FIG. 7, the controller 10 may include the receiver 100, and the memory device 20 may include the driver 200. This is described in detail with reference to FIG. 9.

FIG. 8 is a diagram for illustrating a memory device according to example embodiments.

Referring to FIGS. 6 and 8, the controller 10 according to example embodiments may include the driver 200, and the memory device 20 may include the receiver 100. In example embodiments, the memory device 20 may further include at least one of a CA buffer 21, a control logic 22, an address decoder 23, a cell array 24, a DQ buffer 25, an R/W circuit 26, and an R/W operating part 27.

The receiver 100 may receive a toggle signal from an external device. According to example embodiments, the toggle signal may include at least one of a clock signal CK, a write clock signal WCK, and a data strobe signal DQS. The external device may be the driver 200 of the controller 10. In example embodiments, the write clock signal WCK may be a signal with a higher frequency than the clock signal CK. In example embodiments, the write clock signal WCK may be a signal with a higher frequency than the data strobe signal DQS.

The receiver 100 according to example embodiments may include the duty adjustment module 110, the duty monitoring module 120, and the duty monitoring determination module 130. In example embodiments, the receiver 100 may further include at least one of a mode register 140, a clock buffer 150, a write clock buffer 160, and a DQS buffer 170.

In example embodiments, the mode register 140 may store final monitoring result values on a plurality of code values. In example embodiments, the mode register 140 may store an adjusting code value.

The clock buffer 150 may receive the clock signal CK. The clock signal CK may have a lower frequency than the write clock signal WCK. The clock buffer 150 may provide the received clock signal CK to other components of the memory device 20. For example, the clock buffer 150 may provide the received clock signal CK to the CA buffer 21. For another example, the clock buffer 150 may provide the received clock signal CK to the control logic 22. In example embodiments, the clock signal CK may be a differential signal.

The write clock buffer 160 may receive the write clock signal WCK. The write clock buffer 160 may provide the received write clock signal WCK to other components of the memory device 20. For example, the write clock buffer 160 may provide the received write clock signal WCK to the R/W circuit 26. In example embodiments, the write clock signal WCK may be a differential signal.

The DQS buffer 170 may receive or transmit the data strobe signal DQS. The data strobe signal DQS may be synchronized with the transmission of a data signal DQ. For example, at a rising edge or a falling edge of the data strobe signal DQS, the data signal DQ indicating specific data may be received or transmitted.

In example embodiments, the DQS buffer 170 may receive the data strobe signal DQS from the controller 10. When data is stored in the memory device 20, the data strobe signal DQS may be received together with the data signal DQ including data. In another example embodiment, receiving the data strobe signal DQS may be omitted.

In example embodiments, the DQS buffer 170 may transmit the data strobe signal DQS to the controller 10. When data stored in the memory device 20 is read, the data strobe signal DQS may be transmitted together with the data signal DQ including data.

The CA buffer 21 may receive a command/address signal CA. The command/address signal CA may include at least one of a command controlling an operation and an address indicating a storage area. The command/address signal CA may be synchronized with the clock signal CK and transmitted to the CA buffer 21. For example, at a rising edge or a falling edge of the clock signal CK, the command/address signal CA indicating a specific command or address may be received. The CA buffer 21 may sample the command/address signal CA using the clock signal CK received to the clock buffer 150.

In example embodiments, the command may include various types of control commands controlling operation, such as a mode register write (MRW) command, a mode register read (MRR) command, write command, and a read command.

The control logic 22 may control the overall operation of the memory device 20. In example embodiments, the control logic 22 may generate and output a control signal controlling other components of the memory device 20 to perform an operation according to the received command and address.

In example embodiments, the control logic 22 may, when the mode register write command is received, control such that an operation mode of the receiver 100 is changed to a training mode. As changed to the training mode, the duty adjustment module 110 may adjust each duty cycle of a toggle signal received from an external device according to a code value received from the external device, the duty monitoring module 120 may obtain each monitoring result value on the code value, and the duty monitoring determination module 130 may obtain each final monitoring result value on the code value. The duty monitoring determination module 130 may store final monitoring result values on a plurality of code values in the mode register 140.

In example embodiments, the duty monitoring determination module 130 may obtain an adjusting code value among the plurality of code values by comparing the final monitoring result values on the plurality of code values. In this case, the duty monitoring determination module 130 may store the adjusting code value in the mode register 140.

In example embodiments, the duty monitoring determination module 130 may, when a final monitoring result value on an immediately previous code value and a final monitoring result value on a current code value are different, determine and store one of the immediately previous code value and the current code value as the adjusting code value in the mode register 140.

In example embodiments, the duty adjustment module 110 may, when a following toggle signal is received, adjust a duty cycle of the following toggle signal according to the adjusting code value. The following toggle signal may be a toggle signal received after the adjusting code value is stored in the mode register 140.

In example embodiments, the control logic 22 may, when the mode register read command is received, transmit the adjusting code value and/or the final monitoring result value stored in the mode register 140 to the driver 200 of the controller 10. For example, the adjusting code value and/or the final monitoring result value stored in the mode register 140 may be included in the data signal DQ and transmitted through the DQ buffer 25. In this case, the driver 200 may adjust and transmit the duty cycle of the following toggle signal according to the adjusting code value to the receiver 100.

The address decoder 23 may decode an address according to the control of the control logic 22. For example, the address may include a row address and a column address. A specific area of the cell array 24 may be selected according to the address. For the selected area, an operation of storing or reading data may be performed.

The cell array 24 may include a plurality of memory cells. The memory cell may be selected according to the row address and the column address. The memory cell may be the smallest unit that stores data.

In example embodiments, the DQ buffer 25 may receive the data signal DQ from the controller 20. The data signal DQ may include data to be stored in the specific area of the cell array 24. The data signal DQ may be synchronized with the data strobe signal DQS or the write clock signal WCK.

In example embodiments, the DQ buffer 25 may transmit the data signal DQ to the controller 20. The data signal DQ may include data stored in the specific area of the cell array 24. The data signal DQ may be synchronized with the data strobe signal DQS.

The R/W circuit 26 may sample the data signal DQ using the data strobe signal DQS or obtain parallelized data thereof and transmit data to the R/W operating part 27. The R/W circuit 26 may serialize the data read from the cell array 24 through the R/W operating part 27 and transmit the data signal DQ including the serialized data through the DQ buffer 25 to the controller 10. The R/W circuit 26 may deserialize the data signals received from the controller 10 or serialize the data signals received from the cell array 24. In an embodiment, the R/W circuit 26 may include a serializer/deserializer which is a pair of circuit blocks to covert data between parallel and serial formats.

The R/W operating part 27 may receive data from the R/W circuit 26 and store data in a selected memory cell through an input and output line based on the control of the control logic 22. The R/W operating part 27 may detect and provide data outputted through the input and output line from the selected memory cell to the R/W circuit 26. In an embodiment, the R/W operating part 27 may include a bit-line sense amplifier for a read operation and a write driver for a write operation.

FIG. 9 is a diagram for illustrating a controller according to example embodiments.

Referring to FIGS. 7 and 9, the controller 10 according to example embodiments may include the receiver 100, and the memory device 20 may include the driver 200. In example embodiments, the controller 10 may further include at least one of a processor 11, a CA generator 12, a CK generator 13, a WCK generator 14, a DQ transceiver 16, and a data queue 17.

The receiver 100 may receive a toggle signal from an external device. According to example embodiments, the toggle signal may include the data strobe signal DQS. The external device may be the driver 200 of the memory device 20.

The receiver 100 may include the duty adjustment module 110, the duty monitoring module 120, and the duty monitoring determination module 130. The receiver 100 may further include at least one of the mode register 140 and a DQS buffer 15.

In example embodiments, the mode register 140 may store final monitoring result values on a plurality of code values. In example embodiments, the mode register 140 may store an adjusting code value.

The DQS buffer 15 may receive the data strobe signal DQS. The data strobe signal DQS may be synchronized with the reception of the data signal DQ. In example embodiments, the DQS buffer 15 may transmit the data strobe signal DQS.

The processor 11 may control the overall operation of the controller 10. The processor 11 may control other components. The processor 11 may execute a program and process data. For example, the processor 11 may include at least one of a central processing unit (CPU), a digital signal processing unit (DSP), and an application processor (AP).

The CA generator 12 may generate and store a command and/or an address in a queue. The CA generator 12 may transmit the command/address signal CA including the command or the address to the memory device 20 in an order of being stored in the queue.

The CK generator 13 may generate and output the clock signal CK to the memory device 20. The clock signal CK may be a signal with a lower frequency than the write clock signal WCK. The clock signal CK may be synchronized with the command/address signal CA and transmitted together. In example embodiments, the clock signal CK may be a differential signal.

The WCK generator 14 may generate and output the write clock signal WCK to the memory device 20. In example embodiments, the write clock signal WCK may be synchronized with the data signal DQ and transmitted together. In example embodiments, the write clock signal WCK may be a differential signal.

The DQ transceiver 16 may receive the data signal DQ including read data read from the memory device 20. The DQ transceiver 16 may transmit the data signal DQ including write data to be stored in the memory device 20.

In example embodiments, the data queue 17 may store read data received from the memory device 20. In this case, the read data stored in the data queue 17 may be outputted in sequence. In example embodiments, the data queue 17 may store write data. In this case, the write data stored in the data queue 17 may be outputted in sequence to the memory device 20.

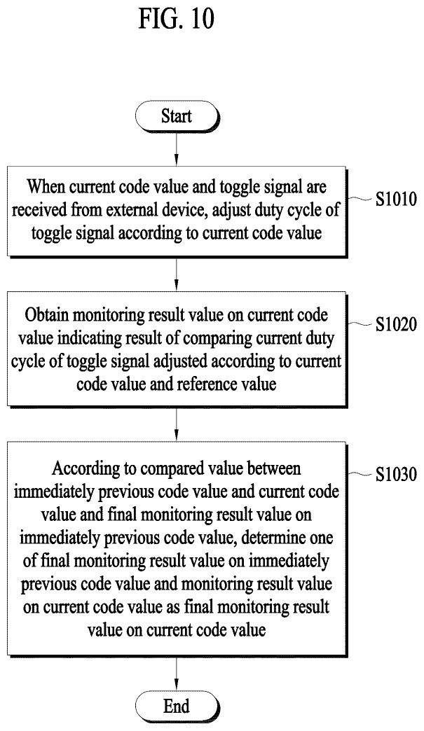

FIG. 10 is a diagram for illustrating an operating method of a receiver according to example embodiments.

Referring to FIG. 10, an operating method of the receiver 100 according to example embodiments of the present disclosure may include, when a current code value and a toggle signal are received from an external device, adjusting a duty cycle of the toggle signal according to the current code value (operation S1010), obtaining a monitoring result value on the current code value indicating a result of comparing a current duty cycle of the toggle signal whose duty cycle is adjusted and a reference value (operation S1020), and according to a compared value between an immediately previous code value and the current code value and a final monitoring result value on the immediately previous code value, determining one of the final monitoring result value on the immediately previous code value and the monitoring result value on the current code value as a final monitoring result value on the current code value (operation S1030).

In example embodiments, the operating method of the receiver 100 may further include receiving the current code value from the external device and then receiving the toggle signal. In example embodiments, the operating method of the receiver 100 may further include receiving the current code value together with the toggle signal from the external device. Each code value may correspond to a time to adjust a duty cycle. In example embodiments, the time may be advanced or delayed based on signs of the code value.

In example embodiments, the operating method of the receiver 100 may further include obtaining the current duty cycle of the toggle signal whose duty cycle is adjusted. In example embodiments, obtaining the current duty cycle of the toggle signal whose duty cycle is adjusted may include identifying a rising edge and a falling edge of the toggle signal using a reference level and obtaining the current duty cycle based on a time between the rising edge and the falling edge.

In example embodiments, in obtaining a monitoring result value on the current code value indicating a result of comparing a current duty cycle and a reference value (operation S1020), the reference value may be a value indicating 0.5 or 50 %.

In example embodiments, according to a compared value between an immediately previous code value and the current code value and a final monitoring result value on the immediately previous code value, determining one of the final monitoring result value on the immediately previous code value and the monitoring result value on the current code value as a final monitoring result value on the current code value (operation S1030) may include, when the compared value is a value indicating an order of increasing code values and the final monitoring result value on the immediately previous code value is a value indicating that the duty cycle is less than 50 %, determining the monitoring result value on the current code value as the final monitoring result value on the current code value.

In example embodiments, determining a final monitoring result value on the current code value (operation S1030) may include, when the compared value is a value indicating an order of increasing code values and the final monitoring result value on the immediately previous code value is a value indicating that the duty cycle is greater than or equal to 50 %, determining the final monitoring result value on the immediately previous code value as the final monitoring result value on the current code value.

In example embodiments, determining a final monitoring result value on the current code value (operation S1030) may include, when the compared value is a value indicating an order of decreasing code values and the final monitoring result value on the immediately previous code value is a value indicating that the duty cycle is less than 50 %, determining the final monitoring result value on the immediately previous code value as the final monitoring result value on the current code value.

In example embodiments, determining a final monitoring result value on the current code value (operation S1030) may include, when the compared value is a value indicating an order of decreasing code values and the final monitoring result value on the immediately previous code value is a value indicating that the duty cycle is greater than or equal to 50 %, determining the monitoring result value on the current code value as the final monitoring result value on the current code value.

The electronic apparatus according to the above-described example embodiments may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. The computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The example embodiments may be represented by functional block elements and various processing steps. The functional blocks may be implemented in any number of hardware and/or software configurations that perform specific functions. For example, an example embodiment may adopt integrated circuit configurations, such as memory, processing, logic, and/or look-up table, which may execute various functions by the control of one or more microprocessors or other control devices. Similarly, these elements may be implemented as software programming or software elements, and the example embodiments may be implemented in a programming or scripting language such as C, C++, Java, and assembler, including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means,” and “configuration” may be used broadly and are not limited to mechanical and physical configurations. The terms may include the meaning of a series of routines of software in association with a processor.

The above-described example embodiments are merely examples, and other example embodiments may be implemented within the scope of the claims to be described later.

What is claimed is:

1. A receiver comprising:
a duty adjustment module configured to:
receive a current code value and a first toggle signal from an external device,
adjust a duty cycle of the first toggle signal according to the current code value to generate a second toggle signal with an adjusted duty cycle, and
output the second toggle signal;
a duty monitoring module configured to:
receive the second toggle signal, and
output a monitoring result value on the current code value, wherein the monitoring result value indicates a result of comparing a current duty cycle of the second toggle signal and a reference value; and
a duty monitoring determination module configured to determine, based on a compared value between the current code value and an immediately previous code value and a final monitoring result value on the immediately previous code value, one of the monitoring result value on the current code value and the final monitoring result value on the immediately previous code value as a final monitoring result value on the current code value.

2. The receiver of claim 1,
wherein the duty monitoring module is configured to:
obtain a first value as the monitoring result value on the current code value in response to the current duty cycle being less than the reference value, and
obtain a second value as the monitoring result value on the current code value in response to the current duty cycle being greater than or equal to the reference value.

3. The receiver of claim 2,
wherein the duty monitoring determination module includes a code comparator configured to:
output a third value as the compared value in response to the current code value being greater than the immediately previous code value, and
output a fourth value as the compared value in response to the current code value being less than the immediately previous code value.

4. The receiver of claim 3,
wherein the duty monitoring determination module further includes a multiplexer configured to output the one of the monitoring result value on the current code value and the final monitoring result value on the immediately previous code value as the final monitoring result value on the current code value in response to the compared value outputted from the code comparator and the final monitoring result value on the immediately previous code value.

5. The receiver of claim 4,
wherein the multiplexer is configured to output the monitoring result value on the current code value as the final monitoring result value on the current code value in response to the third value of the compared value and a first value of the final monitoring result value on the immediately previous code value.

6. The receiver of claim 4,
wherein the multiplexer is configured to output the final monitoring result value on the immediately previous code value as the final monitoring result value on the current code value in response to the third value of the compared value and a second value of the final monitoring result value on the immediately previous code value.

7. The receiver of claim 4,
wherein the multiplexer is configured to output the final monitoring result value on the immediately previous code value as the final monitoring result value on the current code value in response to the fourth value of the compared value and a first value of the final monitoring result value on the immediately previous code value.

8. The receiver of claim 4,
wherein the multiplexer is configured to output the monitoring result value on the current code value as the final monitoring result value on the current code value in response to the fourth value of the compared value and a second value of the final monitoring result value on the immediately previous code value,.

9. The receiver of claim 1,
wherein the duty monitoring module is configured to:
identify a third time for which a state of the second toggle signal is maintained as a first state and a fourth time for which the state is maintained as a second state, and
obtain the current duty cycle by dividing the third time by a sum value of the third time and the fourth time.

10. The receiver of claim 1, further comprising:
a mode register configured to store one of the current code value and the immediately previous code value as an adjusting code value in response to the final monitoring result value on the current code value which is different from the final monitoring result value on the immediately previous code value,
wherein the duty adjustment module is configured to adjust a duty cycle of a toggle signal received after receiving the first toggle signal according to the adjusting code value.

11. An electronic system comprising:
a driver configured to transmit a current code value and a toggle signal; and
a receiver configured to:
receive the current code value and a first toggle signal from the driver,
adjust a duty cycle of the first toggle signal according to the current code value to generate a second toggle signal with an adjusted duty cycle,
obtain a monitoring result value on the current code value, wherein the monitoring result value indicates a result of comparing a current duty cycle of the second toggle signal and a reference value,
obtain a compared value between the current code value and an immediately previous code value of the current code value, and
determine, based on the compared value and a final monitoring result value on the immediately previous code value, one of the final monitoring result value on the immediately previous code value and the monitoring result value on the current code value as a final monitoring result value on the current code value.

12. The electronic system of claim 11, further comprising:
a memory device including one of the driver and the receiver; and
a controller configured to control the memory device and including the other of the driver and the receiver.

13. The electronic system of claim 12,
wherein the toggle signal includes a write clock signal,
wherein the memory device includes the receiver and a write clock buffer configured to receive the write clock signal, and
wherein the controller includes the driver.

14. The electronic system of claim 13,
wherein the toggle signal includes a clock signal with a lower frequency than the write clock signal, and
wherein the receiver further includes a clock buffer configured to receive the clock signal.

15. The electronic system of claim 12,
wherein the toggle signal includes a data strobe signal synchronized with data signal transmission,
wherein the controller includes the receiver and a data strobe (DQS) buffer configured to receive the data strobe signal, and
wherein the memory device includes the driver.

16. The electronic system of claim 11,
wherein the receiver is configured to:
obtain the current duty cycle of the second toggle signal from a flip signal in which a state of the second toggle signal is reversed, and
obtain the monitoring result value on the current code value indicating the result of comparing the current duty cycle and the reference value.

17. The electronic system of claim 11,
wherein the receiver is configured to store one of the immediately previous code value and the current code value as an adjusting code value in a mode register in response to the final monitoring result value on the current code value which is different from the final monitoring result value on the immediately previous code value.

18. The electronic system of claim 17,
wherein the receiver is configured to:
receive a following toggle signal after the adjusting code value is stored, and
adjust a duty cycle of the following toggle signal according to the adjusting code value.

19. The electronic system of claim 17, further comprising:
a control logic configured to transmit, in response to a mode register read command, the adjusting code value to the driver,
wherein the driver is configured to:
adjust a duty cycle of a following toggle signal according to the adjusting code value, and
transmit the following toggle signal with an adjusted duty cycle according to the adjusting code value to the receiver.

20. An operating method of a device comprising:
performing a training mode on a receiver of the device to set an adjusting code value; and
performing a normal operation mode on the device after the training mode is completed, wherein a duty cycle of a toggle signal received in the normal operation mode is adjusted using the adjusting code value,
wherein performing the training mode includes:
receiving a current code value and a first toggle signal from an external device;
adjusting a duty cycle of the first toggle signal according to the current code value to generate a second toggle signal with an adjusted duty cycle of the first toggle signal;
obtaining a monitoring result value on the current code value indicating a result of comparing a current duty cycle of the second toggle signal and a reference value, wherein the current duty cycle of the second toggle signal corresponds to the adjusted duty cycle of the first toggle signal;
generating a compared value between the current code value and an immediately previous code value of the current code value;
determining, in response to the compared value and a final monitoring result value on the immediately previous code value, one of the final monitoring result value on the immediately previous code value and the monitoring result value on the current code value as a final monitoring result value on the current code value; and
storing one of the current code value and the immediately previous code value as the adjusting code value in response to the final monitoring result value on the current code value which is different from the final monitoring result value on the immediately previous code value.
